(19) United States
(12) Patent Application Publication
(10) Pub. No.: US 2017/0256569 A1
(43) Pub. Date: Sep. 7, 2017

(54) SEMICONDUCTOR DEVICE AND DISPLAY DEVICE AND MANUFACTURING METHOD THEREOF

(71) Applicant: Japan Display Inc., Tokyo (JP)

(72) Inventor: Hiroki OHARA, Tokyo (JP)

(21) Appl. No.: 15/340,320

(22) Filed: Nov. 1, 2016

(30) Foreign Application Priority Data
Mar. 7, 2016 (JP) 2016-043117

(51) Int. Cl. H01L 27/12; H01L 29/49; H01L 21/268; H01L 21/02; H01L 21/477; H01L 21/324; H01L 29/786; H01L 29/66

(52) U.S. Cl. CPC H01L 27/1248; H01L 27/1222; H01L 27/1225; H01L 29/7869; H01L 29/78675; H01L 29/4908; H01L 27/1259; H01L 29/66969; H01L 29/66757; H01L 21/02164; H01L 21/0217; H01L 21/477; H01L 21/324; H01L 21/268

(57) ABSTRACT

Provided is a semiconductor device including a first transistor having an oxide semiconductor film, an interlayer film over the first transistor, and second transistor located over the interlayer film and having a semiconductor film including silicon. The interlayer film can include an inorganic insulator. The semiconductor film including silicon can contain polycrystalline silicon. The interlayer film can include an inorganic insulator.

### CROSS REFERENCE TO RELATED APPLICATIONS

This application is based on and claims the benefit of priority from the prior Japanese Patent Application No. 2016-043117, filed on Mar. 7, 2016, the entire contents of which are incorporated herein by reference.

### FIELD

The present invention relates to a semiconductor device, a display device having the semiconductor device, and a manufacturing method thereof.

### BACKGROUND

As a typical example which exhibits a semiconductor property, the Group 14 elements such as silicon and germanium are represented. In particular, silicon is used in almost all semiconductor devices due to its widespread availability, facility in processing, excellent semiconductor properties, ease of controlling their properties, and the like, and is positioned as a core material of the electronics industry.

In recent years, a semiconductor property was discovered in oxides, especially, oxides of the Group 13 elements such as indium and gallium, which has motivated energetic research and development. As a typical oxide (hereinafter, referred to as an oxide semiconductor) exhibiting a semiconductor property, indium-gallium oxide (IGO), indium-gallium-zinc oxide (IGZO), and the like have been known. The resent energetic research has realized the commercialization of a display device having a transistor including an oxide semiconductor as a semiconductor element. Additionally, as disclosed in Japanese patent application publication No. 2015-225104, a semiconductor device has been developed, which includes both a transistor with a semiconductor including silicon (hereinafter, referred to as a silicon semiconductor) and a transistor including an oxide semiconductor.

### SUMMARY

An embodiment of the present invention is a display device including: a substrate; a display region located over the substrate and having a pixel including a display element; and a driver circuit located over the substrate and configured to control the display element. The pixel includes: a first transistor including an oxide semiconductor film and electrically connected to the display element; an interlayer film over the first transistor; and a second transistor over the interlayer film, where the second transistor is electrically connected to the first transistor and has a semiconductor film including silicon.

An embodiment of the present invention is a method for manufacturing a semiconductor device. The method includes: forming a first transistor including an oxide semiconductor film over a substrate; forming an interlayer film over the first transistor; and forming a second transistor over the interlayer film, wherein the second transistor is electrically connected to the first transistor and has a semiconductor film including silicon.

### BRIEF DESCRIPTION OF DRAWINGS

FIG. 1 is a schematic cross-sectional view of a semiconductor device which is an embodiment of the present invention;

FIG. 2 is a schematic cross-sectional view of a semiconductor device which is an embodiment of the present invention;

FIG. 3 is a schematic cross-sectional view of a semiconductor device which is an embodiment of the present invention;

FIG. 4 is a schematic cross-sectional view of a semiconductor device which is an embodiment of the present invention;

FIG. 5A to FIG. 5D are each a schematic cross-sectional view showing a manufacturing method of a semiconductor device which is an embodiment of the present invention;

FIG. 6A to FIG. 6C are each a schematic cross-sectional view showing a manufacturing method of a semiconductor device which is an embodiment of the present invention;

FIG. 7A and FIG. 7B are each a schematic cross-sectional view showing a manufacturing method of a semiconductor device which is an embodiment of the present invention;

FIG. 8A and FIG. 8B are each a schematic cross-sectional view showing a manufacturing method of a semiconductor device which is an embodiment of the present invention;

FIG. 9 is a schematic cross-sectional view showing a manufacturing method of a semiconductor device which is an embodiment of the present invention;

FIG. 10 is a schematic top view of a display device which is an embodiment of the present invention;

FIG. 11 is an equivalent circuit of a pixel a display device which is an embodiment of the present invention;

FIG. 12 is a schematic cross-sectional view of a display device which is an embodiment of the present invention;

FIG. 13 is a schematic cross-sectional view of a display device which is an embodiment of the present invention;

FIG. 14 is a schematic cross-sectional view of a display device which is an embodiment of the present invention;

FIG. 15 is a schematic cross-sectional view of a display device which is an embodiment of the present invention; and

FIG. 16 is a schematic cross-sectional view of a display device which is an embodiment of the present invention.

### DESCRIPTION OF EMBODIMENTS

Hereinafter, the embodiments of the present invention are explained with reference to the drawings. However, the invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film which is formed as the same layer in the same process. Therefore, the plurality of films is defined as films existing in the same layer.

In the invention, unless specifically stated, when a state is expressed where a structure is arranged “over” another structure, such expression includes both a case where the substrate is arranged immediately above the “another structure” so as to be in contact with the “another structure” and a case where the structure is arranged over the “another structure” with an additional structure therebetween.

### First Embodiment

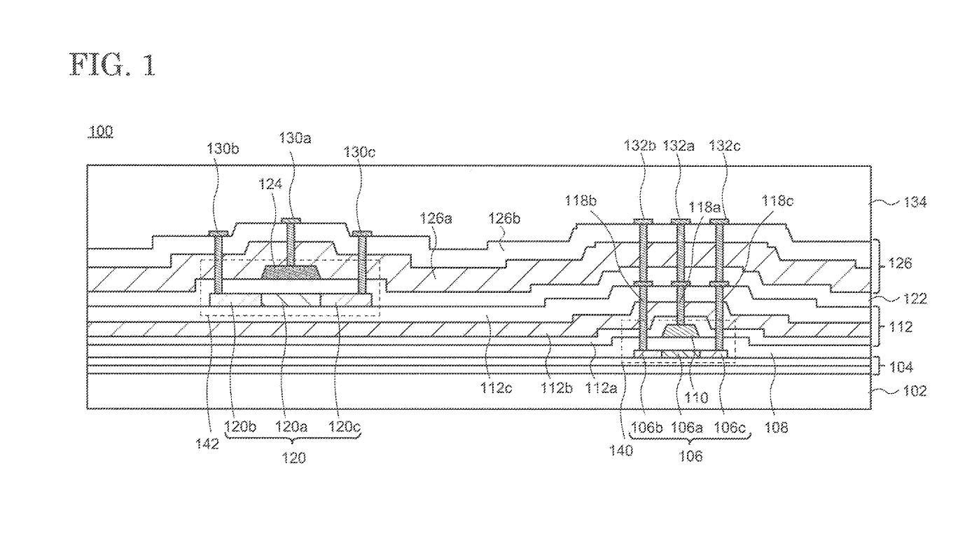

In the present embodiment, a semiconductor device according to an embodiment of the present invention is explained with reference to FIG. 1 to FIG. 4.

### 1. Semiconductor Device 100

A cross-sectional view of a semiconductor device 100 which is a semiconductor device according to the present embodiment is shown in FIG. 1. The semiconductor device 100 has a first transistor 140 and a second transistor 142. The first transistor 140 possesses a semiconductor film (oxide semiconductor film) including an oxide semiconductor. On the other hand, the second transistor 142 possesses a semiconductor film (silicon semiconductor film) including silicon. A first interlayer film 112 is formed over the first transistor 140, and the second transistor 142 is arranged over the first interlayer film 112. Note that, although transistors such as the first transistor 140 and the second transistor 142 are illustrated so as to have a top contact-top gate structure with a single gate in the specification, the embodiment of the present invention is not limited thereto, and each transistor may have a bottom-gate structure or a multi-gate structure having a plurality of gates. Moreover, the transistors may have a bottom-contact structure.

More specifically, the semiconductor device 100 has a substrate 102 and an undercoat 104 over the substrate 102. The substrate 102 has a function to support elements such as the first transistor 140 and the second transistor 142 disposed thereover. The undercoat 104 is a film to prevent impurities from being diffused from the substrate 102 to the first transistor 140 and the second transistor 142. In FIG. 1, the undercoat 104 is illustrated to have a structure in which two layers are stacked. However, the undercoat 104 may have a single layer structure or a stacked structure with three or more layers.

The semiconductor device 100 has the first transistor 140 over the undercoat 104. The first transistor 140 possesses a first gate insulating film 108 over the oxide semiconductor film 106 and a first gate 110 over the first gate insulating film 108.

The oxide semiconductor film 106 can include a Group 13 element such as indium and gallium. The oxide semiconductor film 106 may include a plurality of Group 13 elements different from each other and may be a mixed oxide (an indium-gallium oxide, hereinafter, referred to as IGO) of indium and gallium. The oxide semiconductor film 106 may further include a Group 12 element and is exemplified by a mixed oxide including indium, gallium, and zinc (indium-gallium-zinc oxide, hereinafter, referred to as IGZO). The oxide semiconductor film 106 may include another element such as tin which is a Group 14 element, titanium or zirconium which is a Group 4 element, or the like. There is no limitation to the crystallinity of the oxide semiconductor film 106, and the oxide semiconductor film 106 may be single crystal, polycrystal, microcrystal, or amorphous. The oxide semiconductor film 106 is preferred to have few crystal defects such as an oxygen defect. As shown in FIG. 1, the oxide semiconductor film 106 may have a channel region 106a and source-drain regions 106b and 106c including an impurity. The source-drain regions 106b and 106c may have a higher impurity concentration than the channel region 106a, which results in a larger number of crystal defects and higher conductivity.

The first gate insulating film 108 can include an inorganic insulator and preferably includes an inorganic insulator containing silicon. For example, the first insulating film 108 can include silicon oxide, silicon nitride, silicon nitride oxide, silicon oxynitride, or the like. The first gate insulating film 108 is preferred to have a low concentration of hydrogen and possess oxygen in an amount close to or more than stoichiometry.

The first gate 110 can be formed by using a metal such as titanium, aluminum, copper, molybdenum, tungsten, and tantalum or an alloy thereof so as to have a single layer or stacked layer structure. When the semiconductor device 100 is applied to a semiconductor device having a large area, such as a display device, it is preferred to use a metal having high conductivity, such as aluminum, in order to prevent signal delay.

The first interlayer film 112 can include an inorganic insulator usable in the first gate insulating film 108, for example, and may have a single layer structure or a stacked layer structure. For instance, the first interlayer film 112 can include three layers (first layer 112a, second layer 112b, and third layer 112c) as shown in FIG. 1. In this case, the first interlayer film 112 may be structured so that the first layer 112a and the third layer 112c include silicon oxide, and the second layer 112b includes silicon nitride. It is preferred that the first layer 112a close to the oxide semiconductor film 106 has a low concentration of hydrogen and possess oxygen in an amount close to or more than stoichiometry.

Openings reaching the first gate 110 and the source-drain regions 106b and 106c are formed in the first gate insulating film 108 and the first interlayer film 112, and first wirings 118a, 118b, and 118c are disposed therein. The first wirings 118a, 118b, and 118c are electrically connected to the first gate 110 and the source-drain regions 106b and 106c, respectively.

The second transistor 142 over the first interlayer film 112 has a silicon semiconductor film 120, a second gate insulating film 122 over the silicon semiconductor film 120, and a second gate 124 over the second gate insulating film 122.

The silicon semiconductor film 120 can include single crystalline silicon, polycrystalline silicon, microcrystalline silicon, or amorphous silicon. Hereinafter, an example is described in which the silicon semiconductor film 120 has polycrystalline silicon. The silicon semiconductor film 120 can also have a channel region 120a and source-drain regions 120b and 120c, and the source-drain regions 120b and 120c have a higher impurity concentration compared with the channel region 120a, leading to higher conductivity thereof. As an impurity, an element such as boron and aluminum which provides a p-type conductivity to the silicon semiconductor film 120, an element such as phosphorous and nitrogen which provides a n-type conductivity to the silicon film 120 are given.

The second gate insulating film 122 can include an inorganic insulator usable in the first gate insulating film 108 and may have a single layer structure or a stacked layer structure.

The second gate 124 can have a material and a structure which are applicable to the first gate 110. The second transistor 142 shown in FIG. 1 has the so-called self-align structure, and the second gate 124 does not substantially overlap with the source-drain regions 120b and 120c. However, as described above, the second transistor 142 may have another structure other than the self-align structure and can have a structure such as a bottom-gate structure, a multi-gate structure, and a bottom-contact structure.

The semiconductor device 100 further possesses a second interlayer film 126 over the second transistor 142. In the present embodiment, the second interlayer film 126 is illustrated so as to have two layers (first layer 126a and second layer 126b). However, the second interlayer film 126 may have a single layer structure or a stacked layer structure including three or more layers. The second interlayer film 126 can include a material usable in the first interlayer film 112. For example, the first layer 126a located on a side close to the first transistor 140 may include silicon nitride, and the second layer 126b may include silicon oxide.

Openings reaching the second gate 124 and the source-drain regions 120b and 120c are formed in the second gate insulating film 122 and the second interlayer film 126, and second wirings 130a, 130b, and 130c are disposed therein, respectively. The second wirings 130a, 130b, and 130c are electrically connected to the second gate 124 and the source-drain regions 120b and 120c, respectively. Similarly, openings reaching the first wirings 118a, 118b, and 118c are provided, and the second wirings 132a, 132b, and 132c are disposed therein, respectively. The second wirings 132a, 132b, and 132c are electrically connected to the first wirings 118a, 118b, and 118c, respectively.

The semiconductor device 100 may have a leveling film 134 as an optional structure. The leveling film 134 absorbs projections and depressions caused by the elements formed thereunder, such as the first transistor 140 and the second transistor 142, and has a function to give a flat surface. The leveling film 134 can include an organic insulator which is represented by a polymer material such as an epoxy resin, an acrylic resin, a polyimide, a polyamide, a polycarbonate, and a polysiloxane. Alternatively, the leveling film 134 may include an inorganic insulator usable in the first gate insulating film 108.

As described above, the semiconductor device 100 of the present embodiment possesses, over the substrate 102, two transistors (first transistor 140 and second transistor 142) which are different in material of the semiconductor film governing the electrical property. The oxide semiconductor film 106 is included in the transistor (first transistor 140) on a side close to the substrate 102, while the other transistor (second transistor 142) possesses the silicon semiconductor film 120. As described below, the use of such a structure allows a heat treatment to be performed on the oxide semiconductor film 106 at a sufficiently high temperature and further permits a transistor including an oxide semiconductor film and a transistor including a silicon semiconductor film, which have excellent electrical properties, to coexist in one semiconductor device. The former is characterized in a low off current, a large on current, and small variation in properties, while the latter is characterized in a high field-effect mobility. Therefore, it is possible to provide a semiconductor device having these properties simultaneously.

As described below, a heat treatment can be performed after doping an impurity to the silicon semiconductor film 120. In this case, hydrogen is released from the silicon semiconductor film 120 and diffused in the films close to the silicon semiconductor film 120. For example, in the semiconductor device 100 shown in FIG. 1, hydrogen from the silicon semiconductor film 120 is diffused to the second interlayer film 126 and the like. As hydrogen influences the electrical properties of the oxide semiconductor film, the formation of the first transistor 140 including the oxide semiconductor film 106 over the second interlayer film 126 causes the diffusion of hydrogen to the oxide semiconductor film 106, resulting in fluctuation of a threshold and variation of electrical properties of the first transistor 140.

In contrast, in the semiconductor device 100 shown in FIG. 1, the second transistor 142 including the silicon semiconductor film 120 is located over the top-gate type first transistor 140 including the oxide semiconductor film 106 with the first interlayer film 112 interposed therebetween. This structure enables an increase in distance between the silicon semiconductor film 120 and the oxide semiconductor film 106. Hence, it is possible to reduce the influence of hydrogen released from the silicon semiconductor film 120, giving a transistor including an oxide semiconductor film and having excellent electrical properties.

### 2. Semiconductor Device 200

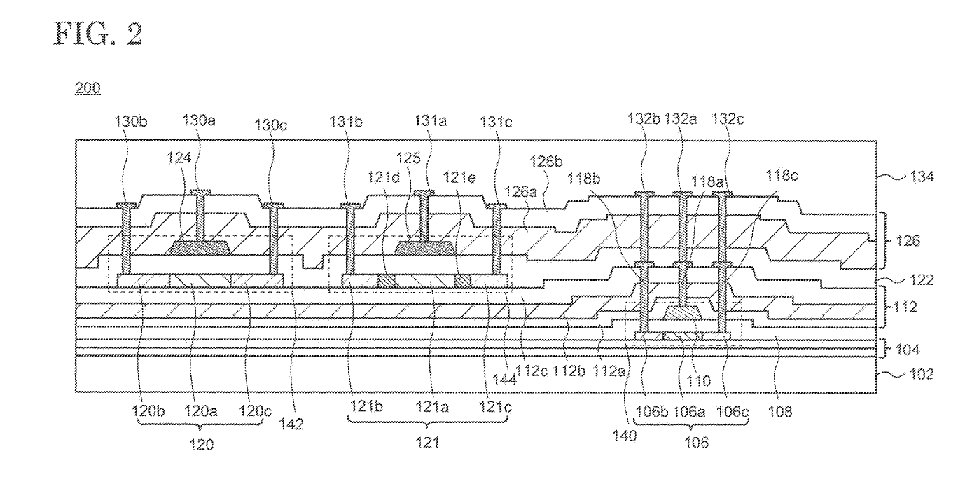

A schematic cross-sectional view of a semiconductor device 200 which is a semiconductor device of the present embodiment is shown in FIG. 2. An explanation of the structures which are the same as those of the semiconductor device 100 may be omitted.

Similar to the semiconductor device 100, the semiconductor device 200 has the first transistor 140 including the oxide semiconductor film 160 over the substrate 102, the first interlayer film 112 over the first transistor 140, and the second transistor 142 located over the first interlayer film 112 and including the silicon semiconductor film 120. The semiconductor device 200 further possesses a third transistor 144 over the first interlayer film 112. The third transistor 144 has a silicon semiconductor film 121 and a third gate 125 over the silicon semiconductor film 121 with the second gate insulating film 122 interposed therebetween. Thus, the silicon semiconductor film 120 and the silicon semiconductor film 121 exist in the same layer as each other, and the second gate 124 and the third gate 125 also exist in the same layer as each other.

The silicon semiconductor film 121 can have the same material and the same crystallinity as the silicon semiconductor film 120. The silicon semiconductor film 121 includes a channel region 121a, source-drain regions 121b and 121c, and low-concentration impurity regions 121d and 121e. The low-concentration impurity regions 121d and 121e are high in impurity concentration and in conductivity compared with the channel region 121a. Moreover, the source-drain regions 121b and 121c are high in impurity concentration and in conductivity compared with the low-concentration impurity regions 121d and 121e. Note that, similar to the third transistor 144, the second transistor 142 may also have low-concentration impurity regions. On the contrary, similar to the second transistor 142, the third transistor 144 may not include the low-concentration impurity region, and the source-drain regions 120b and 120c may be in contact with the channel region 121a.

As an impurity included in the source-drain regions 121b and 121c and the low-concentration impurity regions 121d and 121e of the third transistor 144, an element such as phosphorous and nitrogen which provides a n-type conductivity to the silicon semiconductor film 121 and an element such as boron and aluminum which provides a p-type conductivity to the silicon semiconductor film 121 are given. For example, the source-drain regions 120b and 120c of the second transistor 142 may include an element providing a p-type conductivity as an impurity, and the source-drain regions 121b and 121c and the low-concentration impurity regions 121d and 121e of the third transistor 144 may include an element providing a n-type conductivity as an impurity. Moreover, one of the source-drain regions 120b and 120c of the second transistor 142 and one of the source-drain regions 121b and 121c of the third transistor 144 can be electrically connected to each other, thereby forming a complementary metal-oxide semiconductor (CMOS) transistor.

The third gate 125 can have a material and a structure which are the same as those of the second gate 124.

Openings reaching the third gate 125 and the source-drain regions 121b and 121c are provided in the second gate insulating film 122 and the second interlayer film 126, and second wirings 131a, 131b, and 131c are disposed therein, respectively. The second wirings 131a, 131b, and 131c are electrically connected to the third gate 125 and the source-drain regions 121b and 121c, respectively.

Similar to the aforementioned semiconductor device 100, the semiconductor device 200 has, over the substrate 102, two kinds of three transistors (first transistor 140, second transistor 142, and third transistor 144) which are different in material of the semiconductor film governing the electrical properties. The oxide semiconductor film 106 is included in the transistor (first transistor 140) on a side close to the substrate 102, while the two transistors (second transistor 142 and third transistor 144) on a side far from the substrate 102 contain the silicon semiconductor films 120 and 121. As described below, the use of such a structure allows a heat treatment to be performed on the oxide semiconductor film 106 at a sufficiently high temperature and also permits a transistor including an oxide semiconductor film and a transistor including a silicon semiconductor film, which have excellent electrical properties, to coexist in one semiconductor device, by which a semiconductor device having excellent electrical properties can be supplied.

Similar to the semiconductor device 100, the oxide semiconductor film 106 can be spaced from the silicon semiconductor films 120 and 121 in the semiconductor device 200, by which the influence of hydrogen which may be released from the silicon semiconductor films 120 and 121 can be minimized. Hence, a transistor including an oxide semiconductor film having excellent electrical properties can be provided.

### 3. Semiconductor Device 300

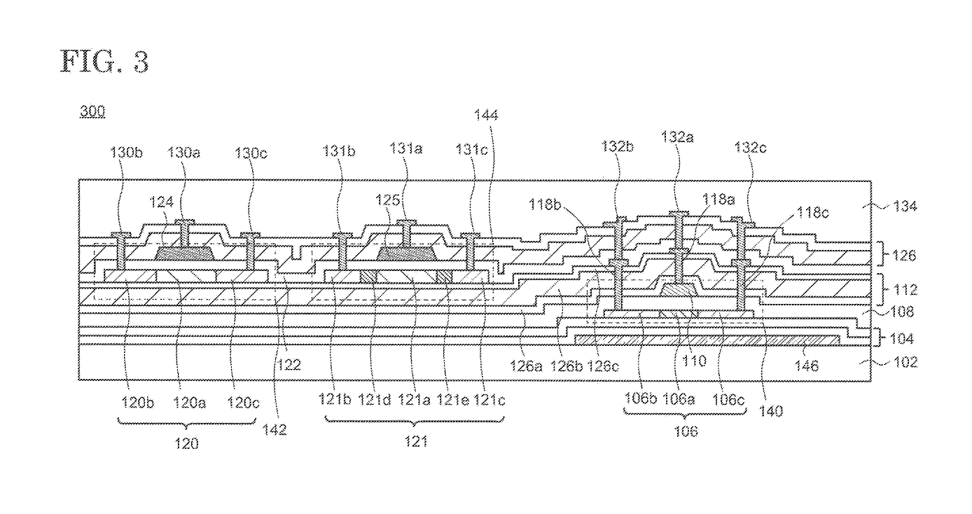

A schematic cross-sectional view of a semiconductor device 300 which is a semiconductor device of the present embodiment is shown in FIG. 3. An explanation of the structures which are the same as those of the semiconductor devices 100 and 200 may be omitted.

The semiconductor device 300 has a metal film 146 under the first transistor 140. Specifically, the semiconductor device 300 has the metal film 146 between the substrate 102 and the undercoat 104. The metal film 146 can include a metal such as chromium and have a function to shield visible light. Note that, when the undercoat 104 is structured by a plurality of layers, the metal film 146 may be formed so as to be sandwiched therebetween. As described below, when the semiconductor films 120 and 121 are crystallized by irradiation of light such as a laser, the metal film 146 is able to shield the first transistor 140 from the light, by which photo-induced deterioration of properties of the first transistor 140 can be prevented.

The metal film 146 may be configured so as to be electrically connected to the first gate 110 and be supplied with the same potential. Alternatively, the metal film 146 may be configured so as to be supplied with a potential different from that of the first gate 110. Alternatively, the metal film 146 may be configured so as to be supplied with a constant current. With these structures, the metal film 146 can also function as a back gate of the first transistor 140 by which the threshold and the off current of the first transistor 140 can be controlled.

Similar to the aforementioned semiconductor devices 100 and 200, the semiconductor device 300 has two kinds of transistors (first transistor 140 and second transistor 142) which are different in material of the semiconductor film governing the electrical properties. As described below, the use of such a structure allows heat treatment to be performed on the oxide semiconductor film 106 at a sufficiently high temperature and also permits a transistor including an oxide semiconductor film and a transistor including a silicon semiconductor film, which have excellent electrical properties, to coexist in one semiconductor device, by which a semiconductor device having excellent electrical properties can be supplied.

### 4. Semiconductor Device 400

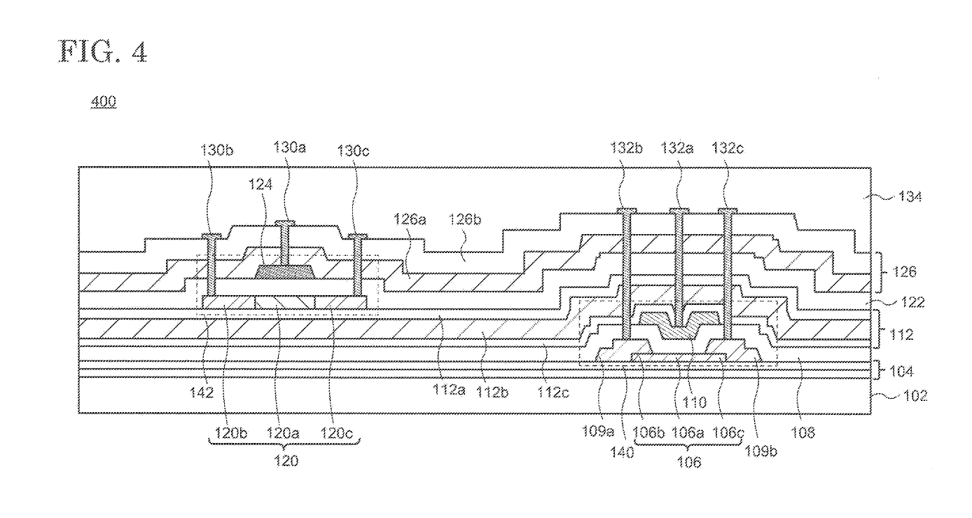

A schematic cross-sectional view of a semiconductor device 400 which is a semiconductor device of the present embodiment is shown in FIG. 4. An explanation of the structures which are the same as those of the semiconductor devices 100, 200, and 300 may be omitted.

Similar to the semiconductor device 100, the semiconductor device 400 has the first transistor 140 including the oxide semiconductor film 106 over the substrate 102 and the second transistor 142 including the silicon semiconductor film 120 with the first interlayer film 112 interposed therebetween. The first transistor 140 has source-drain electrodes 109a and 109b over and in contact with the oxide semiconductor 106. Although a part of the first gate 110 overlaps with the source-drain electrodes 109a and 109b in FIG. 4, the first gate 110 may be arranged so as not to overlap with the source-drain electrodes 109a and 109b. Here, different from the semiconductor devices 100, 200, and 300, the first wiring 118a, 118b. and 118c are not provided, openings reaching the silicon semiconductor film 120 and the source-drain electrodes 109a and 109b are formed simultaneously, and the second wirings 130a, 130b, 130c 132a, 132b, and 132c are formed simultaneously. As described below, as the source-drain electrodes 109a and 109b function as an etching stopper in such a structure, the oxide semiconductor film 106 is not etched or contaminated when the openings are formed. Additionally, the manufacturing process can be further simplified.

Although not illustrated, similar to the semiconductor device 300, the semiconductor device 400 may have the metal film 146 between the substrate 102 and the first transistor 146, for example, between the substrate 102 and the undercoat 104. Furthermore, the metal film 146 may be configured so as to be electrically connected to the first gate 110 and be supplied with the same potential. Alternatively, the metal film 146 may be configured so as to be supplied with a potential different from that of the first gate 110. Alternatively, the metal film 146 may be configured to be supplied with a certain constant current.

Similar to the aforementioned semiconductor devices 100, 200, and 300, the semiconductor device 400 has, over the substrate 102, two transistors (first transistor 140 and second transistor 142) which are different in material of the semiconductor film governing the electrical properties. As described below, the use of such a structure allows heat treatment to be performed on the oxide semiconductor film 106 at a sufficiently high temperature and also permits a transistor including an oxide semiconductor film and a transistor including a silicon semiconductor film, which have excellent electrical properties, to coexist in one semiconductor device, by which a semiconductor device having excellent electrical properties can be supplied.

### Second Embodiment

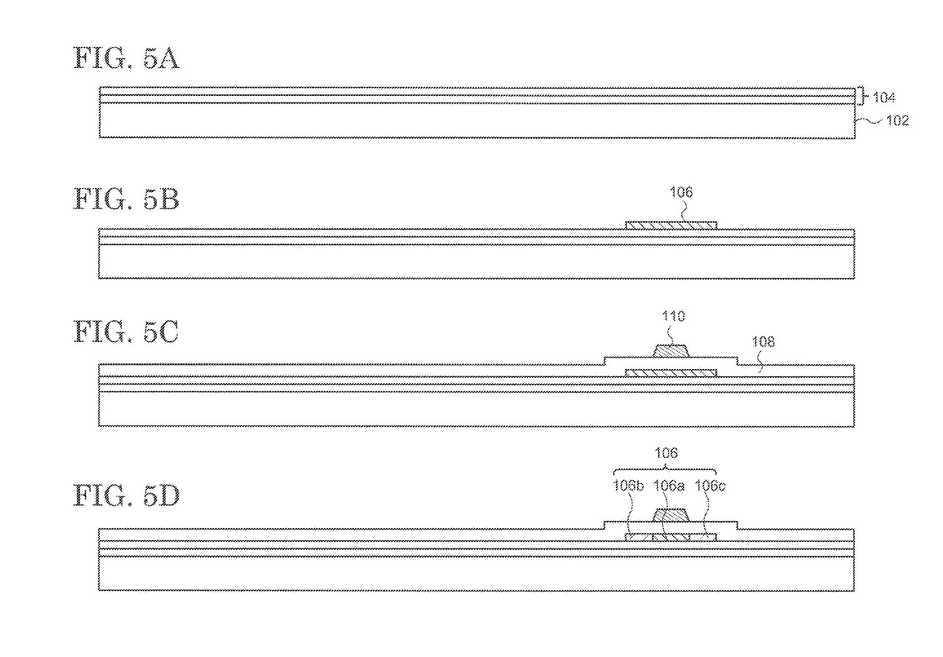

In the present embodiment, a manufacturing method of a semiconductor device according to an embodiment of the present invention is explained with reference to FIG. 5A to FIG. 9. An explanation is provided using the semiconductor device 200 described in the First Embodiment as an example of the semiconductor device. An explanation of the contents which are the same as those of the First Embodiment may be omitted.

### 1. Undercoat

As shown in FIG. 5A, the undercoat 104 is formed over the substrate 102. For the substrate 102, a material which has a heat-resisting property to the temperature of the following process and chemical stability to chemicals used in the process may be used. Specifically, the substrate 102 can include glass, quartz, plastic, a metal, ceramics, and the like. When flexibility is provided to the semiconductor device 200, a material including plastic can be used, and a polymer material exemplified by a polyimide, a polyamide, a polyester, and a polycarbonate can be employed, for example. Note that when a flexible semiconductor device 200 is fabricated, the substrate 102 may be called a base substrate or a base film.

The undercoat 104 is a film having a function to prevent impurities such as an alkaline metal from being diffused to the first transistor 140, the second transistor 142, and the like from the substrate 102 and may include an inorganic insulator such as silicon nitride, silicon oxide, silicon nitride oxide, and silicon oxynitride. The undercoat 104 can be formed by applying a chemical vapor deposition method (CVD method), a sputtering method, and the like, and a thickness can be selected freely from a range of 50 nm to 1000 nm. When a CVD method is used, tetraalkoxysilane and the like may be used as a raw-material gas. The thickness of the undercoat 104 is not necessarily constant over the substrate 102, and the undercoat 104 may have a different thickness in a different position. When the undercoat 104 is structured with a plurality of layers, a layer including silicon nitride may be stacked over the substrate 102, and then a layer including silicon oxide may be stacked thereover, for example.

Note that when the impurity concentration in the substrate 102 is low, the undercoat 104 may not be disposed or may be formed so as to partly cover the substrate 102. For example, when a polyimide having a low concentration of an alkaline metal is used, the undercoat 104 may not be formed, and the oxide semiconductor film 106 may be disposed so as to be in contact with the substrate 102.

### 2. Oxide Semiconductor Film

Next, the oxide semiconductor film 106 of the first transistor 140 is formed over the undercoat 104 (FIG. 5B). The oxide semiconductor film 106 can include an oxide exhibiting a semiconductor property, such as IGZO and IGO. The oxide semiconductor film 106 is formed by forming an oxide semiconductor film with a thickness of 20 nm to 80 nm or 30 nm to 50 nm over the undercoat 104 with a sputtering method and the like, followed by patterning the oxide semiconductor film.

When the oxide semiconductor film 106 is formed with a sputtering method, the film formation can be conducted under an atmosphere including an oxygen gas, such as a mixed atmosphere of argon and an oxygen gas. In this case, a partial pressure of argon may be smaller than that of the oxygen gas. A current applied to a target may be a direct current or an alternating current and can be determined on the basis of the shape, composition, and the like of the target. As the target, a mixed oxide (InₐGa_{b}Zn_{c}O_{d}) including indium (In), gallium (Ga), and zinc (Zn) can be used, for example. Here, a, b, c and d are each a real number equal to or larger than 0 and are not necessarily an integral number. Therefore, if each element is assumed to exist in the most stable ionic state, the aforementioned composition is not necessarily an electrically neutral composition. As an example of the target composition, InGaZnO₄ is represented. However, the composition is not limited thereto and can be appropriately selected so that the oxide semiconductor film 106 or the first transistor 140 exhibits an aimed property.

A heat treatment (annealing) may be performed on the oxide semiconductor film 106. The heat treatment may be conducted before the patterning or after the patterning of the oxide semiconductor film 106. It is preferred that the heat treatment be performed before the patterning because the oxide semiconductor film 106 may be reduced in volume (shrinking) by the heat treatment.

The heat treatment may be conducted in the presence of nitrogen, dried air, or atmospheric air at a normal pressure or a reduced pressure. The heating temperature can be selected from a range of 250° C. to 500° C. or 350° C. to 450° C., and the heating time can be selected from a range of 15 minutes to 1 hour. However, the heat treatment can be conducted outside these temperatures and time ranges. Oxygen is introduced or migrated to the oxygen defects of the oxide semiconductor film 106 by the heat treatment, which results in the oxide semiconductor film 106 having a well-defined structure, a small number of crystal defects, and high crystallinity. Accordingly, the first transistor 140 having a high reliability and excellent electrical properties such as a high on current, a low off current, and a low property (threshold voltage) variation.

### 3. First Gate Insulating Film

Next, the first gate insulating film 108 is formed over the oxide semiconductor film 106 (FIG. 5C). The first gate insulating film 108 preferably includes a silicon-containing inorganic insulator such as silicon oxide, silicon nitride, silicon oxynitride, and silicon nitride oxide, for example. The first insulating film 108 can be formed by applying a sputtering method, a CVD method, or the like. It is preferred that the atmosphere in the film formation include a hydrogen-containing gas such as hydrogen gas and vapor as little as possible, by which the first gate insulating film 108 having a low hydrogen concentration and oxygen in an amount close to or more than stoichiometry can be formed.

### 4. First Gate

Next, the first gate 110 is formed over the first gate insulating film 108 (FIG. 5C). The first gate 110 can be formed with a metal such as aluminum, copper, molybdenum, tungsten, and tantalum or an alloy thereof so as to have a single layer structure or a stacked layer structure. For example, a stacked structure in which a highly conductive metal such as aluminum and copper is sandwiched by a metal having a high melting point, such as titanium and molybdenum, can be employed. The first gate 110 is formed by forming a film containing the aforementioned metal over a top surface of the first gate insulating film 108 with a sputtering method, a CVD method, a printing method, or the like, followed by processing the film with etching (dry etching, wet etching).

### 5. Source-Drain Region

The first transistor 140 of the semiconductor device 200 has the so-called self-align structure. When this structure is formed, the first gate 110 is used as a mask, and ion-implantation treatment (or ion-doping treatment) is performed on the oxide semiconductor film 106 from over the substrate 102. By this method, an ion is doped into a region of the oxide semiconductor film 106, which does not overlap with the first gate 110, as an impurity with respect to the oxide semiconductor film 106. The oxide semiconductor film 106 becomes a n-type by the ion-doping and decreases in electric resistance. As a result, the source-drain regions 106b and 106c are formed, and the channel region 106a which is not substantially doped with ions is simultaneously formed (FIG. 5D).

As the ion, an ion of boron, phosphorous, nitrogen, and the like can be used. The dose amount of the ion and the ion-acceleration energy are adjusted so that the decrease in resistance occurs at a vicinity of the top surface of the oxide semiconductor film 106. It is considered that the change into the n-type takes place by inducing the oxygen-defect formation upon the ion-doping or by the carrier generation resulting from the movement of ions into a lattice interstice.

### 6. First Interlayer Film

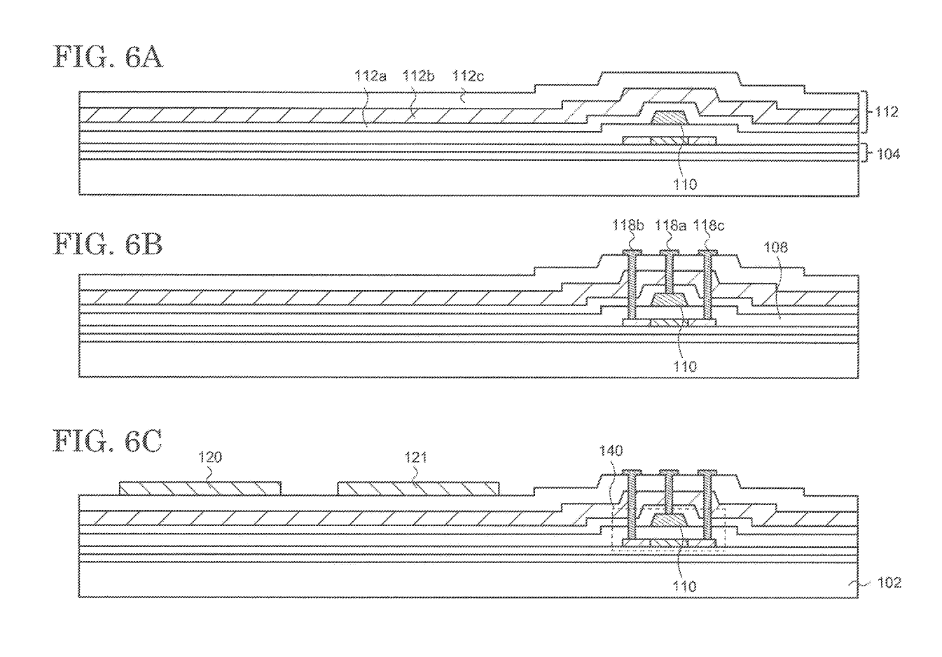

Next, the first interlayer film 112 is formed over the first gate 110 (FIG. 6A). The first interlayer film 112 can include a material usable in the undercoat 104 and can be formed with a sputtering method and a CVD method. Alternatively, the first interlayer film 112 may include aluminum oxide, chromium oxide, boron nitride, and the like.

The first interlayer film 112 may have a single layer structure or a stacked layer structure. When the first interlayer film 112 has a stacked structure, it can be formed by stacking the first layer 112a including silicon oxide, the second layer 112b including silicon nitride, and the third layer 112c including silicon oxide, for example.

After that, the openings are formed in the first gate insulating film 108 and the first interlayer film 112 to expose the first gate 110 and the source-drain regions 106b and 106c. The openings can be formed by dry etching, and a fluorine-containing gas such as CF₄ can be used as an etching gas. The first wirings 118a, 118b, and 118c are formed in these openings (FIG. 6B), by which the first wirings 118a, 118b, and 118c are electrically connected to the first gate 110 and the source-drain regions 106b and 106c, respectively. The first wirings 118a, 118b, and 118c can be formed with a material and a method which can be used and applied in the first gate 110. It is preferred to use aluminum having a low electrical resistance. Note that, as described below, the opening formation can be performed after the formation of the second transistor 142 and the third transistor 144.

### 7. Silicon Semiconductor Film

Next, the silicon semiconductor films 120 and 121 of the second transistor 142 and the third transistor 144 are formed over the first interlayer film 112 (FIG. 6C). For example, amorphous silicon (a-Si) is formed to a thickness of approximately 50 nm to 100 nm with a CVD method and is crystallized by a heat treatment or irradiation of light such as a laser to result in a polycrystalline silicon (polysilicon) film. The crystallization may be conducted in the presence of a catalyst such as nickel.

The light may be applied from over or under the substrate 102. When the first transistor 140 is prevented from being irradiated with light, the metal film 146 shown in the semiconductor device 300 is formed under the first transistor 140 in advance (see, FIG. 3), and then light is applied from under the substrate 102, for example. Note that when the crystallinity of the oxide semiconductor film 106 is improved with light-irradiation, the oxide semiconductor film 106 may be also irradiated with light when the a-Si is crystallized. The improvement of the crystallinity of the oxide semiconductor film 106 provides a large difference in etching rate between the oxide semiconductor film 106 and the first gate insulating film 108 and between the oxide semiconductor film 106 and the first interlayer film 112 when the openings to form the first wirings 118a, 118b, and 118c are formed.

### 8. Second Gate Insulating Film, Second Gate, and Third Gate

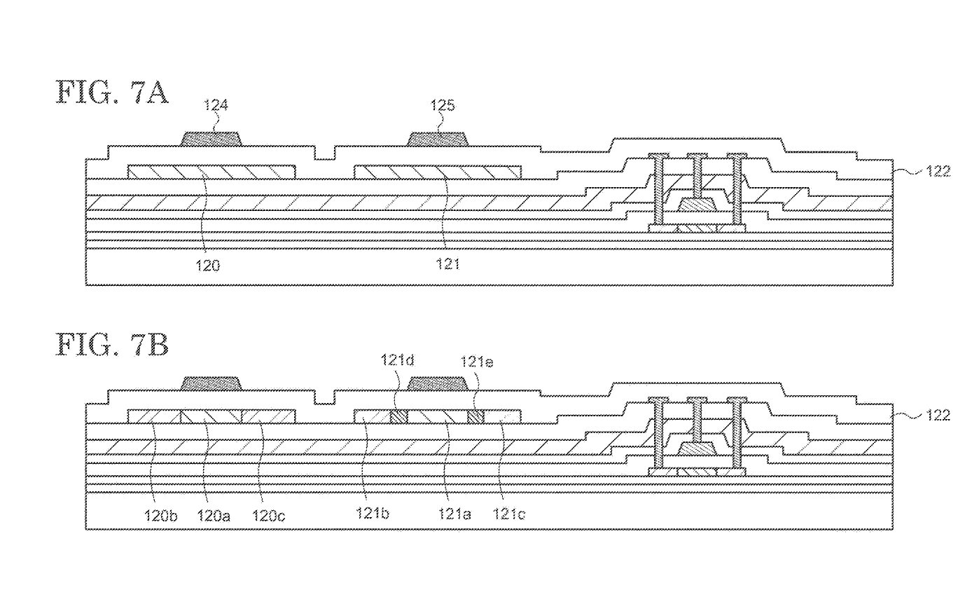

Next, the second gate insulating film 122 is formed so as to cover the silicon semiconductor films 120 and 121 and the first transistor 140 (FIG. 7A). The second gate insulating film 122 can be formed by applying the same material and method adopted for the first gate insulating film 108.

The second gate insulating film 122 may have a higher hydrogen concentration than the first gate insulating film 108. The higher hydrogen concentration of the second gate insulating film 122 than that of the first gate insulating film 108 allows the formation of the second transistor 142 and the third transistor 144 having excellent electrical properties. However, entrance of hydrogen to the oxide semiconductor film 106 significantly degrades the semiconductor property. Therefore, it is preferred to increase the distance between the second gate insulating film 122 and the oxide semiconductor film 106. Therefore, the first transistor 140 is preferably a top-gate type.

The second gate 124 and the third gate 125 are formed over the second gate insulating film 122 so as to overlap with the silicon semiconductor films 120 and 121, respectively (FIG. 7A). The second gate 124 and the third gate 125 can be formed with a material and method which are the same as those of the first gate 110. When the semiconductor device according to the embodiment of the present invention is applied to a large-area semiconductor device such as a display device, for example, it is preferred to use a highly conductive metal such as aluminum in order to avoid signal delay.

### 9. Source-Drain Region

After that, an ion-implantation treatment or an ion-doping treatment is performed on the silicon semiconductor films 120 and 121 from over the substrate 102 using the second gate 124 and the third gate 125 as a mask. In the semiconductor device 300 of the present embodiment, an ion providing a p-type conductivity is doped to the silicon semiconductor film 120 so that the source-drain regions 120b and 120c are formed in the regions of the silicon semiconductor film 120, which do not overlap with the second gate 124, and that the channel region 120a which is not substantially doped with ions is simultaneously formed (FIG. 7B).

On the other hand, an ion providing a n-type conductivity is doped to the silicon semiconductor film 121 so that the source-drain regions 121b and 121c are formed in the regions of the silicon semiconductor film 121, which do not overlap with the third gate 125, and that the channel region 121a which is not substantially doped with ions is simultaneously formed.

As shown in FIG. 7B, the low-concentration impurity regions (LDD) 121d and 121e may be formed between the source-drain region 121b and the channel region 121a and between the source-drain region 121c and the channel region 121a of the silicon semiconductor film 121. In the low-concentration impurity regions 121d and 121e, the concentration of the doped ion is lower than that in the source-drain regions 121b and 121c and higher than that in the channel region 121a. The low-concentration impurity regions 121d and 121e can be formed by forming an insulating film on a side surface of the third gate 125, followed by performing ion-doping therethrough, for example.

A heat treatment may be conducted after the ion doping to activate the doped ion. Through the aforementioned process, the first transistor 140, the second transistor 142, and the third transistor 144 are formed.

### 10. Second Interlayer Film

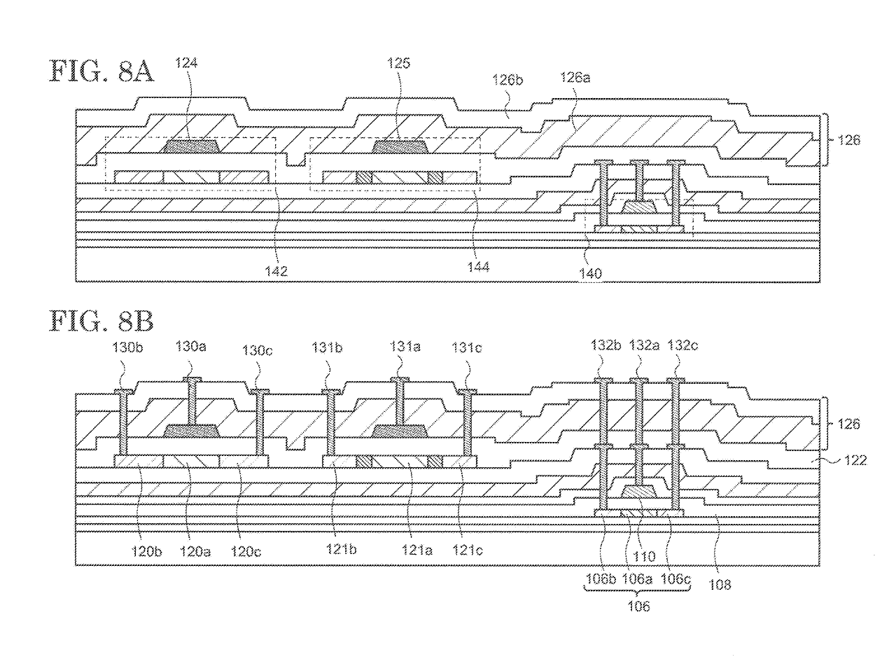

Next, the second interlayer film 126 is formed over the second gate 124 and the third gate 125 (FIG. 8A). The second interlayer film 126 can include a material which is the same as that of the first interlayer film 112 and can be formed by applying the same formation method. For example, the second interlayer film 126 may be formed with a film containing silicon oxide or silicon nitride in a single layer structure or a stacked layer structure. In FIG. 8A, an example is shown in which two layers (first layer 126a and second layer 126b) are included. However, similar to the first interlayer film 112, the second interlayer film 126 may be formed by stacking a first layer including silicon oxide, a second layer including silicon nitride, and a third layer including silicon oxide.

Heat treatment may be conducted after forming the second interlayer film 126 by which the crystal defects generated by the ion doping can be repaired, allowing the silicon semiconductor film 121 to be activated.

After that, the second gate insulating film 122 and the second interlayer film 126 are etched so that the openings reaching the first wirings 118a, 118b, and 118c are formed in addition to the openings which expose the second gate 124, the third gate 125, and the source-drain regions 120b, 120c, 121b, and 121c. Then, the second wirings 130a, 130b, 130c, 131a, 131b, 131c, 132a, 132b, and 132c are formed in these openings. The second wirings 130a, 130b, 130c, 131a, 131b, 131c, 132a, 132b, and 132c can also be formed with a material and method which are the same as those for the first wirings 118a, 118b, and 118c. By this process, the second wrings 130a, 130b, 130c, 131a, 131b, and 131c are electrically connected to the second gate 124, the source-drain regions 120b and 120c, the third gate 125, and the source-drain regions 121b and 121c, respectively. In a similar way, the second wirings 132a, 132b, and 132c are electrically connected to the first wirings 118a, 118b, and 118c, respectively (FIG. 8B).

Prior to the formation of the second wirings 130a, 130b, 130c, 131a, 131b, 131c, 132a, 132b, and 132c in the corresponding openings, a treatment with hydrofluoric acid may be performed in order to wash the surfaces of the silicon semiconductor films 120 and 121, which are exposed in the openings. This washing process can remove an oxide film which may be formed at the surfaces of the silicon semiconductor films 120 and 121 and reduce the contact resistance.

Note that, as shown in FIG. 4, etching may be performed on the first gate insulating film 108, the first interlayer film 112, the second gate insulating film 122, and the second interlayer film 126 simultaneously so that the openings reaching the first gate 110 and the source-drain electrodes 109a and 109b are formed in addition to the openings which expose the second gate 124, the third gate 125, the source-drain regions 120b, 120c, 121b, and 121c without the formation of the first wirings 118a, 118b, and 118c and the openings thereof prior to the formation of the second transistor 142 and the third transistor 144. The first transistor 140 shown in FIG. 4 has a top-contact type top-gate structure, which allows the source-drain electrodes 109a and 109b to function as an etching stopper. Therefore, the oxide semiconductor film 106 does not vanish and is not contaminated during etching, allowing a variety of etching conditions to be employed. Additionally, it becomes unnecessary to form the first wirings 118a, 118b, and 118c, and the second wirings 132b and 132c respectively connected to the source-drain regions 106b and 106c can be simultaneously formed with the second wirings 130a, 130b, 130c, 131a, 131b, and 131c, by which the number of the process can be reduced.

### 11. Leveling Film

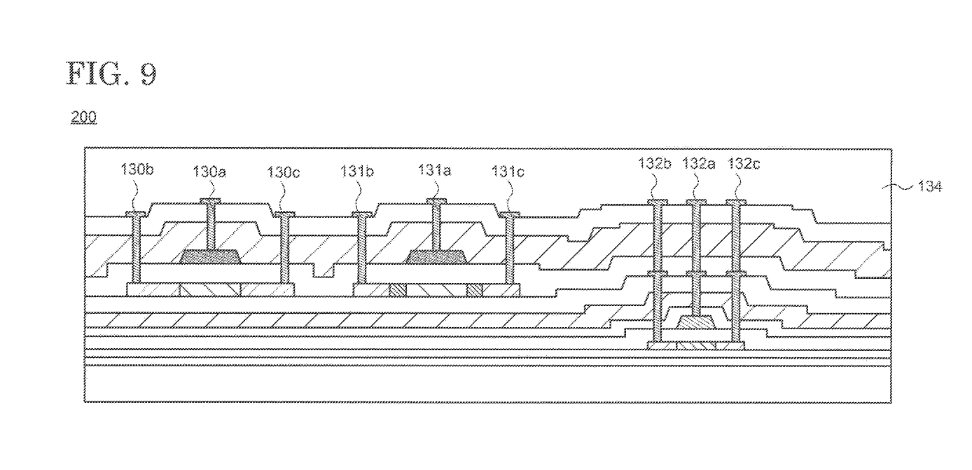

Next, as an optional structure, the leveling film 134 is formed (FIG. 9). The leveling film 134 absorbs the projections and depressions caused by the first transistor 140, the second transistor 142, the third transistor 144, and the like and has a function to give a flat surface. The leveling film 134 can be formed with an organic insulator. As an organic insulator, a polymer material such as an epoxy resin, an acrylic resin, a polyimide, a polyamide, a polyester, a polycarbonate, and a polysiloxane can be represented. The leveling film 134 can be formed by a wet film-forming method such as a spin-coating method, an ink-jet method, a printing method, and a dip-coating method. The leveling film 134 may have a stacked structure including a layer containing the aforementioned organic insulator and a layer containing an inorganic insulator. As an inorganic insulator, a silicon-containing inorganic insulator such as silicon oxide, silicon nitride, silicon nitride oxide, and silicon oxynitride is represented, and the inorganic insulator can be deposited by a sputtering method, a CVD method, and the like.

Through the aforementioned process, the semiconductor device 300 is fabricated.

As described above, the heat treatment on the oxide semiconductor film 106 improves the crystallinity of the oxide semiconductor film 106 and the electrical properties and reliability of the first transistor 140 and further reduces the variation of the properties. The temperature of the heat treatment is relatively high and is preferred to be 250° C. to 500° C. or 350° C. to 450° C. A highly conductive metal such as aluminum which is used in the first gate 110, the second gate 124, the third gate 125, the first wirings 118a, 118b, and 118c, and the second wrings 130a, 130b, 130c, 131a, 131b, and 131c has a low resistivity to such a high temperature. Hence, it is impossible to conduct the heat treatment on the oxide semiconductor film 106 after the second gate 124 or the third gate 125 is formed.

However, as described in the present embodiment, when the semiconductor devices 100, 200, 300, and 400 described in the First Embodiment are fabricated, the first gate 110, the second transistor 142, the third transistor 144, the first wirings 118a, 118b, and 118c, and the second wirings 130a, 130b, 130c, 131a, 131b, and 131c are formed after performing the heat treatment on the oxide semiconductor film 106 of the first transistor 104. Hence, it is possible to prevent the heat treatment which is performed on the oxide semiconductor film 106 at a high temperature from being applied to these elements. Therefore, not only the first transistor 140 including the oxide semiconductor film 106 with excellent electrical properties can be formed but also the second transistor 142 and the third transistor 144 including the silicon semiconductor films 120 and 121 with a high field-effect mobility can be fabricated over the same substrate 102.

Moreover, the application of the present embodiment enables an increase in distance between the silicon semiconductor film 120 and the oxide semiconductor film 106. Hence, influence of the hydrogen released from the silicon semiconductor film 120 can be reduced, and a transistor including an oxide semiconductor film having excellent electrical properties can be provided.

### Third Embodiment

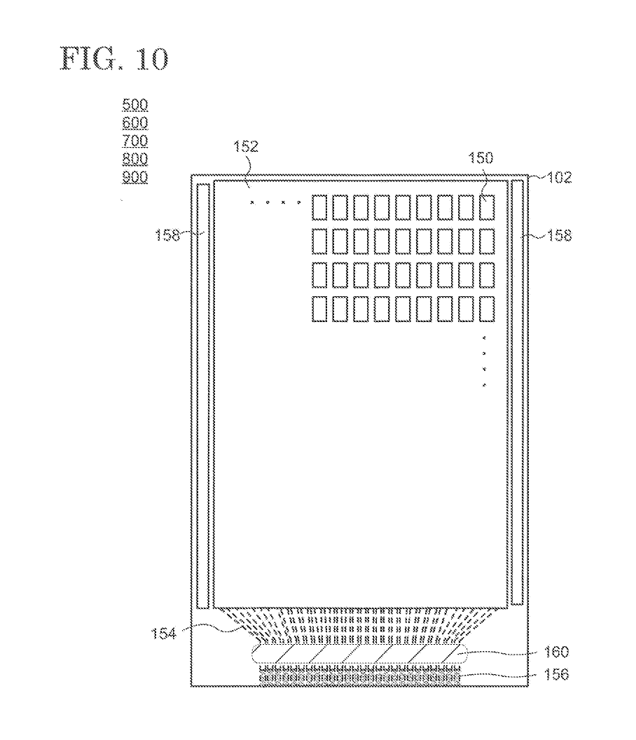

In the present embodiment, a display device having the semiconductor device 100, 200, 300, or 400 described in the First Embodiment and its manufacturing method are explained with reference to FIG. 10 to FIG. 12. Description which is the same as that of the First and Second Embodiments may be omitted.

### 1. Outline Structure

A schematic top view of a display device 500 of the present embodiment is shown in FIG. 10. The display device 500 has a display region 152 including a plurality of pixels 150 and a gate-side driver circuit (hereinafter, referred to as driver circuit) 158 over one surface (top surface) of the substrate 102. The plurality of pixels 150 can be provided with display elements such as light-emitting elements and liquid crystal elements giving different colors from each other, by which a full color display can be achieved. For example, display elements giving red color, green color, and blue color can be disposed in three pixels 150, respectively. Alternatively, display elements giving white color may be used in all pixels 150, and the full color display may be performed by extracting red color, green color, or blue color from respective pixels 150 by using color filters. The colors finally extracted are not limited to the combination of red, green, and blue colors. For example, four kinds of colors including red, green, blue, and white colors may be extracted from four pixels 150. There is no limitation to the arrangement of the pixels 150, and a stripe arrangement, a delta arrangement, a Pentile arrangement, and the like may be employed.

Wirings 154 extend to a side surface (in FIG. 10, a short side of the display device 500) of the substrate 102 from the display region 152, and the wirings 154 are exposed at an edge portion of the substrate102 to form terminals 156. The terminals 156 are connected to a connector (not illustrated) such as a flexible printed circuit (FPC). The display region 152 is also electrically connected to an IC chip 160 via the wirings 154 by which image signals supplied from an external circuit (not illustrated) are provided to the pixels 150 through the driver circuit 158 and the IC chip 160, the display elements in the pixels 150 are controlled, and an image is reproduced on the display region 152. Note that, although not illustrated, the display device 500 may have a source-side driver circuit at a periphery of the display region 152 instead of the IC chip 160. In the present embodiment, two driver circuits 158 are disposed so as to sandwich the display region 152. However, the number of the driver circuit 158 may be one. Additionally, the driver circuit 158 may not be formed over the substrate 102, and the driver circuit 158 formed over another substrate may be mounted over the connector.

### 2. Pixel Circuit

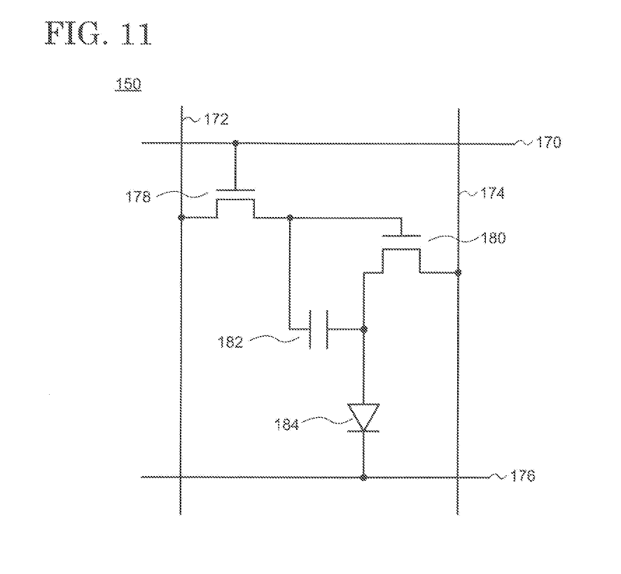

An example of an equivalent circuit of the pixel 150 is shown in FIG. 11. In FIG. 11, an example is shown in which a light-emitting element such as an organic electroluminescence element is arranged as a display element. The pixel 150 has a gate line 170, a signal line 172, a current-supplying line 174, and a power-source line 176.

The pixel 150 has a switching transistor 178, a driving transistor 180, a storage capacitor 182, and the display element 184. A gate, source, and drain of the switching transistor 178 are electrically connected to the gate line 170, the signal line 172, and a gate of the driving transistor 180, respectively. A source of the driving transistor 180 is electrically connected to the current-supplying line 174. One electrode of the storage capacitor 182 is electrically connected to the drain of the switching transistor 178 and the gate of the driving transistor 180, and the other electrode is electrically connected to a drain of the driving transistor 180 and one electrode (first electrode) of the display element 184. The other electrode (second electrode) of the display element 184 is electrically connected to the power-source line 176. In FIG. 11, the display element 184 is illustrated as a light-emitting element having a diode property. Note that, the source and the drain of each transistor may be interchanged depending on the direction of current and the polarity of the transistor.

In FIG. 11, a structure is shown in which the pixel 150 has two transistors (switching transistor 178 and driving transistor 180) and one storage capacitor (storage capacitor 182). However, the display device 500 is not limited to this structure, and the pixel 150 may possess one transistor or three or more transistors. The pixel 150 may not include a storage capacitor or may have a plurality of storage capacitors. Moreover, the display element 184 is not limited to a light-emitting element and can be a liquid crystal element or an electrophoresis element. The wirings are also not limited only to the gate line 170, the signal line 172, the current-supplying line 174, and the power-source line 176, and the pixel 150 may have a plurality of gate lines, for example. Alternatively, at least one of these wirings may be shared by the plurality of pixels 150.

### 3. Cross-Sectional Structure

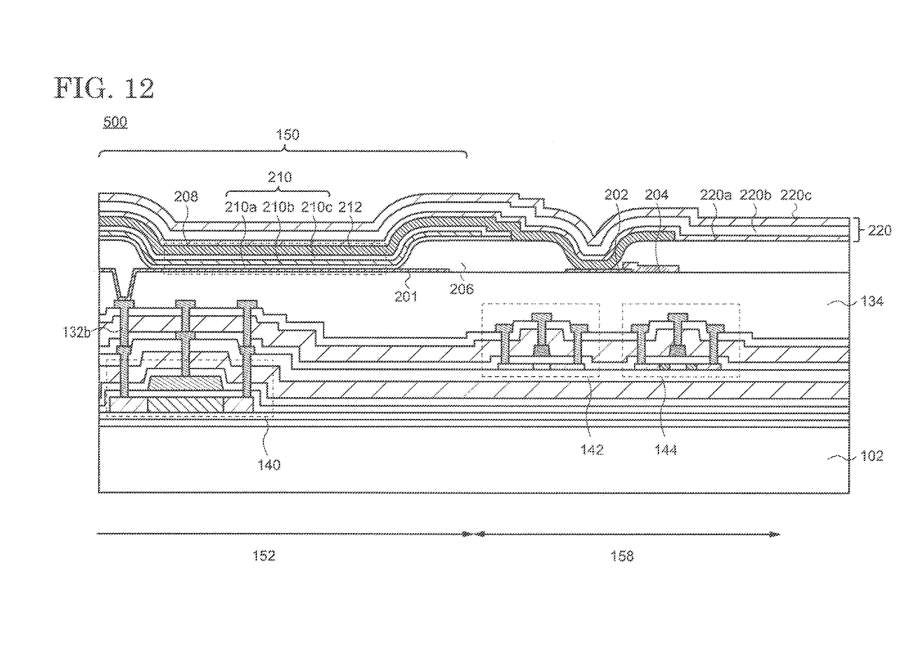

A schematic cross-sectional view of the display device 500 is shown in FIG. 12. FIG. 12 shows one pixel 150 which is closest to the driver circuit 158 among the display region 152, a part of the driver circuit 158, and a peripheral structure thereof. The display device 500 has the semiconductor device 200 described in the First Embodiment. Here, the first transistor 140 of the display device 500 is included in the pixel 150, whereas the second transistor 142 and the third transistor 144 are included in the driver circuit 158.

The display device 500 has the light-emitting element 208 over the leveling film 134. The light-emitting element 208 corresponds to the display element 184 shown in FIG. 11. The light-emitting element 208 has the first electrode 201, and the first electrode 201 is electrically connected to the second wiring 132b in the opening provided in the leveling film 134. The first electrode 201 may be connected to the second wiring 132b via another conductive film.

When the light emission from the light-emitting element 208 is extracted through the substrate 102, a material having a light-transmitting property, such as a conductive oxide exemplified by indium-tin-oxide (ITO) and indium-zinc-oxide (IZO), can be used for the first electrode 201. On the other hand, when the light emission from the light-emitting element 208 is extracted from a side opposite to the substrate 102, a metal such as aluminum and silver or an alloy thereof can be used. Alternatively, a stacked layer of the aforementioned metal or alloy and the conductive oxide can be employed. For example, a stacked structure in which a metal is sandwiched by a conductive oxide (e.g., ITO/silver/ITO etc.) can be used.

An electrode 202 and an auxiliary electrode 204 electrically connected to the electrode 202 are disposed over the leveling film 134. The electrode 202 corresponds to the power-source line 176 in FIG. 11. The electrode 202 can be formed by using a conductive oxide such as ITO and IZO and applying a sputtering method and the like. The electrode 202 can be formed simultaneously with the first electrode 201. Therefore, the second electrode 202 can exist in the same layer as the first electrode 201. The electrode 202 is connected to a second electrode 212 of the light-emitting element 208 formed later and has a function to supply a constant current to the second electrode 212.

The auxiliary electrode 204 may be formed with a metal usable in the first gate 110 and the second gate 124 or an alloy thereof. The auxiliary electrode 204 has a function to supplement the conductivity of the second electrode 212 and is capable of preventing the voltage drop which occurs in the second electrode 212 when a resistance of the second electrode 212 of the light-emitting element 208 formed later is relatively high.

The display device 500 further possesses a partition wall 206. The partition wall 206 has a function to absorb steps caused by an edge portion of the first electrode 201 and the openings formed in the leveling film 134 and to electrically insulate the first electrodes 201 of the adjacent pixels 150 from each other. The partition wall 206 is also called a bank (rib). The partition wall 206 can be formed by using a material usable in the leveling film 134, such as an epoxy resin and an acrylic resin. The partition wall 206 has openings so as to expose a part of the first electrode 201 and a part of the second electrode 202, and edge portions of the openings preferably have a taper shape. A steep slope in the edge portions of the openings readily leads to a coverage defect of an EL layer 210, the second electrode 212, and the like formed later.

The light-emitting element 208 has the EL layer 210, and the EL layer 210 is formed so as to cover the first electrode 201 and the partition wall 206. In the present specification and claims, an EL layer means the whole of the layers sandwiched between a pair of electrodes and may be structured by a single layer or a plurality of layers. For example, the EL layer 210 can be structured by appropriately combining a carrier-injection layer, a carrier-transporting layer, an emission layer, a carrier-blocking layer, an exciton-blocking layer, and the like. Moreover, the EL layer 210 may be different in structure between adjacent pixels 150. For example, the EL layer 210 may be formed so that the emission layer is different but other layers are the same in structure between the adjacent pixels 150. With this structure, different emission colors can be obtained from the adjacent pixels 150, and a full color display can be realized. On the contrary, the same EL layer 210 may be used in all pixels 150. In this case, the EL layer 210 giving white emission may be formed so as to be shared by all pixels 150, and the wavelength of the light extracted from each pixel 150 may be selected by using a color filter and the like.

In FIG. 12, the EL layer 210 has a first layer 21a, a second layer 210b, and a third layer 210c. The first layer 210a and the third layer 210c may be in contact with each other over the partition wall 206. The EL layer 210 can be formed by an evaporation method or the aforementioned wet film-forming method.

The light-emitting element 208 has the second electrode 212 over the EL layer 210. The light-emitting element 208 is structured by the first electrode 201, the EL layer 210, and the second electrode 212. Carriers (electrons and holes) are injected to the EL layer 210 from the first electrode 201 and the second electrode 212, and the light-emission is obtained through a process in which an excited state generated by the recombination of the carriers relaxes to a ground state. Therefore, in the light-emitting element 208, a region in which the EL layer 210 and the first electrode 201 are in direct contact with each other is an emission region.

When the light emission from the light-emitting element 208 is extracted through the substrate 102, a metal such as aluminum and silver or an alloy thereof can be used for the second electrode 212. On the other hand, when the light-emission from the light-emitting element 208 is extracted through the second electrode 212, the second electrode 212 is formed by using the aforementioned metal or alloy so as to have a thickness which allows visible light to pass therethrough. Alternatively, a material having a light-transmitting property, such as a conductive oxide exemplified by ITO, IZO, and the like, can be used for the second electrode 212. Furthermore, a stacked structure of the aforementioned metal or ally with the conductive oxide (e.g., MG-Ag/ITO, etc.) can be employed in the second electrode 212. The second electrode 212 can be formed with an evaporation method, a sputtering method, and the like.

A passivation film (sealing film) 220 is disposed over the second electrode 212. One of the functions of the passivation film 220 is to prevent water from entering the precedently prepared light-emitting element 208 from outside, and the passivation film 220 is preferred to have a high gas-barrier property. For example, it is preferred that the passivation film 220 be formed by using an inorganic material such as silicon nitride, silicon oxide, silicon nitride oxide, or silicon oxynitride. Alternatively, an organic resin including an acrylic resin, a polysiloxane, a polyimide, a polyester, and the like may be used. In the structure exemplified in FIG. 12, the passivation film 220 has a three-layer structure including a first layer 220a, a second layer 220b, and a third layer 220c.

Specifically, the first layer 220a may include an inorganic insulator such as silicon oxide, silicon nitride, silicon nitride oxide, and silicon oxynitride and may be formed by applying a CVD method or a sputtering method. As a material for the second layer 220b, a polymer material selected from an epoxy resin, an acrylic resin, a polyimide, a polyester, a polycarbonate, a polysiloxane, and the like can be used. The second layer 220b can be formed with the aforementioned wet film-forming method. Alternatively, the second layer 220b may be formed by atomizing or gasifying oligomers functioning as a raw material of the polymer material at a reduced pressure, spraying the first layer 220a with the oligomers, and polymerizing the oligomers. At this time, a polymerization initiator may be mixed in the oligomers. Additionally, the first layer 220a may be sprayed with the oligomers while cooling the substrate 102. The third layer 220c can be formed by applying the same material and method as those for the first layer 220a.

Although not illustrated, an opposing substrate may be arranged over the passivation film 220 as an optional structure. The opposing substrate is fixed to the substrate 102 with an adhesive. In this case, a space between the opposing substrate and the passivation film 220 may be filled with an inert gas or a filler such as a resin. Alternatively, the passivation film 220 and the opposing substrate may be directly adhered with an adhesive. When a fill material is used, it is preferred to have a high transmitting property with respect to visible light. When the opposing substrate is fixed to the substrate 102, a gap therebetween may be adjusted by adding a spacer in the adhesive or the filler. Alternatively, a structure functioning as a spacer may be formed between the pixels 150.

Furthermore, a light-shielding film having an opening in a region overlapping with the emission region and a color filter in a region overlapping with the emission region may be disposed over the opposing substrate. The light-shielding film is formed by using a metal with a relatively low reflectance, such as chromium and molybdenum, or a mixture of a resin material with a coloring material having a black or similar color. The light-shielding film has a function to shield or suppress the scattering or reflection of external light other than the light directly obtained from the emission region. The color filter can be formed while changing its optical properties between adjacent pixels 150 so that red emission, green emission, and blue emission are extracted. The light-shielding film and the color filter may be provided over the opposing substrate with an undercoat film interposed therebetween, and an overcoat layer may be further arranged to cover the light-shielding film and the color filter.

The display device 500 shown in the present embodiment has the second transistor 142 and the third transistor 144 including the silicon semiconductor films 120 and 121 in the driver circuit 158. As a transistor including a silicon semiconductor film, especially, a transistor including a polycrystalline silicon semiconductor film has a high field-effect mobility, the driver circuit 158 including such a transistor is capable of high-speed operation. On the other hand, the pixel 150 has the first transistor 140 including the oxide semiconductor film 106. As a transistor including an oxide semiconductor film exhibits a large on current, a large current can be applied to the light-emitting element 208. Furthermore, as a transistor including an oxide semiconductor has small variation of the threshold voltage, variation of the current flowing in the light-emitting element 208 can be reduced. As a result, the display device 500 which can illuminate at a high luminance and provide a high quality image can be supplied.

### Fourth Embodiment

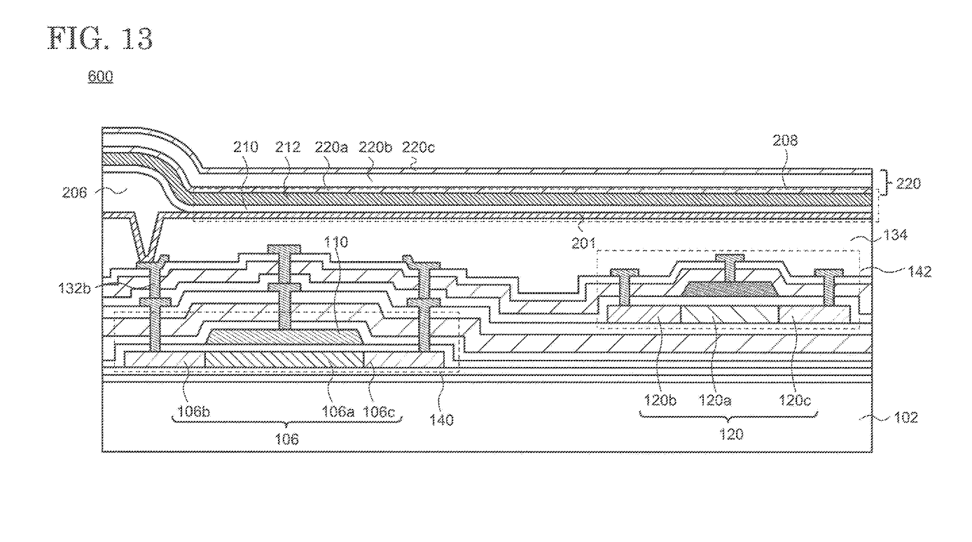

In the present embodiment, a display device including the semiconductor device 100, 200, 300, or 400 described in the First Embodiment and its manufacturing method are explained with reference to FIG. 10, FIG. 11, and FIG. 13. Description which is the same as that in the First to Third Embodiments may be omitted.

A schematic cross-sectional view of a display device 600 is shown in FIG. 13. FIG. 13 corresponds to the schematic cross-sectional view of the pixel 150 shown in FIG. 10. The display device 600 has the semiconductor device 100 described in the First Embodiment in the pixel 150, and the light-emitting element 208 is electrically connected to the first transistor 140 through the second wiring 132b. That is, the first transistor 140 functions as the driving transistor 180 in the pixel 150 shown in FIG. 10. Furthermore, the second transistor 142 corresponds to the switching transistor 178. Although not shown in FIG. 13, one of the source-drain regions 120b and 120c of the second transistor 142 is electrically connected to the first gate 110 of the first transistor 140.

The display device 600 shown in the present embodiment possesses the second transistor 142 including the silicon semiconductor film 120 as the switching transistor 178. As a transistor including a silicon semiconductor film, especially, a transistor including a polycrystalline silicon semiconductor film has a high field-effect mobility, a high-speed switching property can be obtained in the pixel 150. The pixel 150 has the first transistor 140 including the oxide semiconductor film 106 as the driving transistor 180. As a transistor including an oxide semiconductor film exhibits a large on current, a large current can be applied to the light-emitting element 208. Furthermore, as a transistor including an oxide semiconductor has small variation of the threshold voltage, variation of the current flowing in the light-emitting element 208 can be reduced. As a result, the display device 600 which can illuminate at a high luminance and provide a high quality image can be supplied.

### Fifth Embodiment

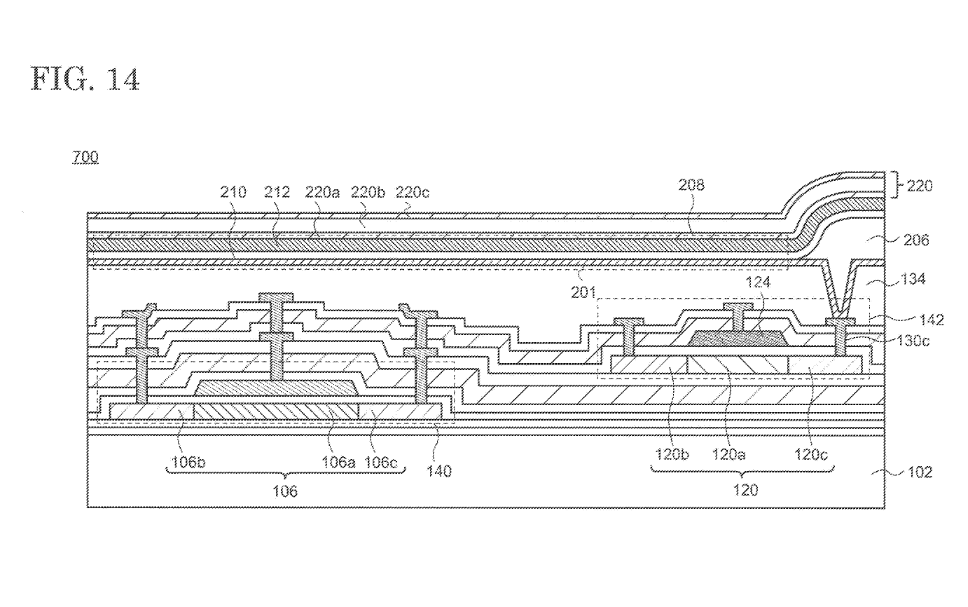

In the present embodiment, a display device including the semiconductor device 100, 200, 300, or 400 described in the First Embodiment and its manufacturing method are explained with reference to FIG. 10, FIG. 11, and FIG. 14. Description which is the same as that in the First to Fourth Embodiments may be omitted.

A schematic cross-sectional view of a display device 700 is shown in FIG. 14. FIG. 14 corresponds to the schematic cross-sectional view of the pixel 150 shown in FIG. 10. The display device 700 has the semiconductor device 100 described in the First Embodiment in the pixel 150, and the light-emitting element 208 is electrically connected to the second transistor 142 through the second wiring 132c. That is, the first transistor 140 functions as the switching transistor 178 in the pixel 150 shown in FIG. 10. Furthermore, the second transistor 142 corresponds to the driving transistor 180. Although not shown in FIG. 14, one of the source-drain regions 106b and 106c of the first transistor 140 is electrically connected to the second gate 124 of the second transistor 142.

The display device 700 shown in the present embodiment possesses the first transistor 140 including the oxide semiconductor film 106 as the switching transistor 178. As a transistor including an oxide semiconductor film exhibits a small off current, image data transmitted from the signal line 172 can be held in the second gate 124 of the second transistor 142 which is the driving transistor 180 or in the storage capacitor 182 for a long period. Therefore, the storage capacitor 182 may not be necessarily provided or can be downsized. As a result, power consumption of the display device 700 can be reduced, and an aperture ratio can be increased. Furthermore, as a transistor including an oxide semiconductor has small variation of the threshold voltage, variation of the current flowing in the light-emitting element 208 can be reduced. As a result, the display device 700 which can provide a high quality image can be supplied.

### Sixth Embodiment

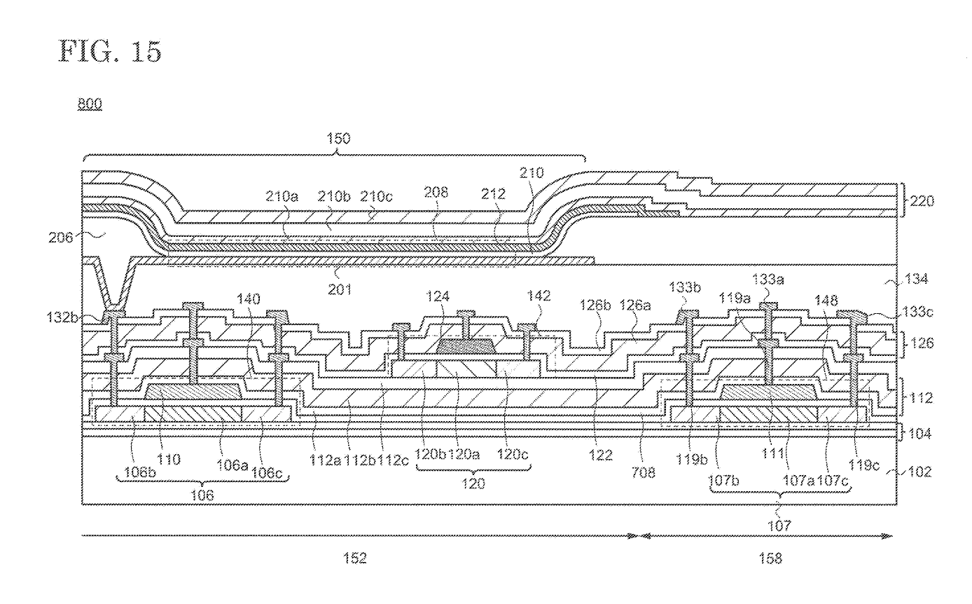

In the present embodiment, a display device including the semiconductor device 100, 200, 300, or 400 described in the First Embodiment and its manufacturing method are explained with reference to FIG. 10, FIG. 11, and FIG. 15. Description which is the same as that in the First to Fifth Embodiments may be omitted.

A schematic cross-sectional view of a display device 800 is shown in FIG. 15. A part of the display region 152 and a part of the driver circuit 158 shown in FIG. 10 are schematically illustrated in FIG. 15. The display device 800 has the semiconductor device 100 described in the First Embodiment in the pixel 150 and possesses a fourth transistor 148 including an oxide semiconductor film 107 in the driver circuit 158.

That is, the driver circuit 158 has the fourth transistor 148 over the undercoat 104, and a fourth gate 111 is arranged over the oxide semiconductor film 107 with the first gate insulating film 108 interposed therebetween. The oxide semiconductor film 107 has a channel region 107a in a region overlapping with the fourth gate 111 and possesses source-drain regions 107b and 107c which sandwich the channel region 107a and which is higher in impurity concentration than the channel region 107a.

Similar to the first transistor 140, wirings 119a, 119b, and 119c are disposed in openings formed in the first gate insulating film 108 and the first interlayer film 112 and are electrically connected to the fourth gate 111 and the source-drain regions 107b and 107c, respectively. Openings are also formed in the second gate insulating film 122 and the second interlayer film 126 in which second wirings 133a, 133b, and 133c are formed. The second wirings 133a, 133b, and 133c are electrically connected to the first wirings 119a, 119b, and 119c, respectively.

In the display device 800, the light-emitting element 208 is electrically connected to the first transistor 140 through the second wring 132b. That is, the first transistor 140 functions as the driving transistor 180 in the pixel 150 shown in FIG. 10. Furthermore, the second transistor 142 corresponds to the switching transistor 178. Although not shown in FIG. 15, one of the source-drain regions 120b and 120c of the second transistor 142 is electrically connected to the first gate 110 of the first transistor 140.

The display device 800 shown in the present embodiment possesses the fourth transistor 148 including the oxide semiconductor film 107 in the driver circuit 158. As a transistor including an oxide semiconductor has small variation of the threshold voltage, it is not necessary to dispose a compensation circuit for compensating the variation. Alternatively, the structure of the compensation circuit can be downsized. Therefore, an area occupied by the driver circuit 158 can be reduced. The display device 800 further has the second transistor 142 including the silicon semiconductor film 120 as the switching transistor 178 in the pixel 150. As a transistor including a silicon semiconductor film, especially, a transistor including a polycrystalline silicon semiconductor film has a high field-effect mobility, a high-speed switching property can be obtained in pixel 150. The pixel 150 further possesses the first transistor 140 including the oxide semiconductor film 106 as the driving transistor 180 shown in FIG. 10. As a transistor including an oxide semiconductor film exhibits a large on current, a large current can be applied to the light-emitting element 208. Furthermore, as a transistor including an oxide semiconductor has small variation of the threshold voltage, variation of the current flowing in the light-emitting element 208 can be reduced. As a result, the light-emitting element 208 is able to emit light at a high luminance, which allows the production of a display device capable of supplying a high quality image and having a driver circuit with a small area.

### Seventh Embodiment

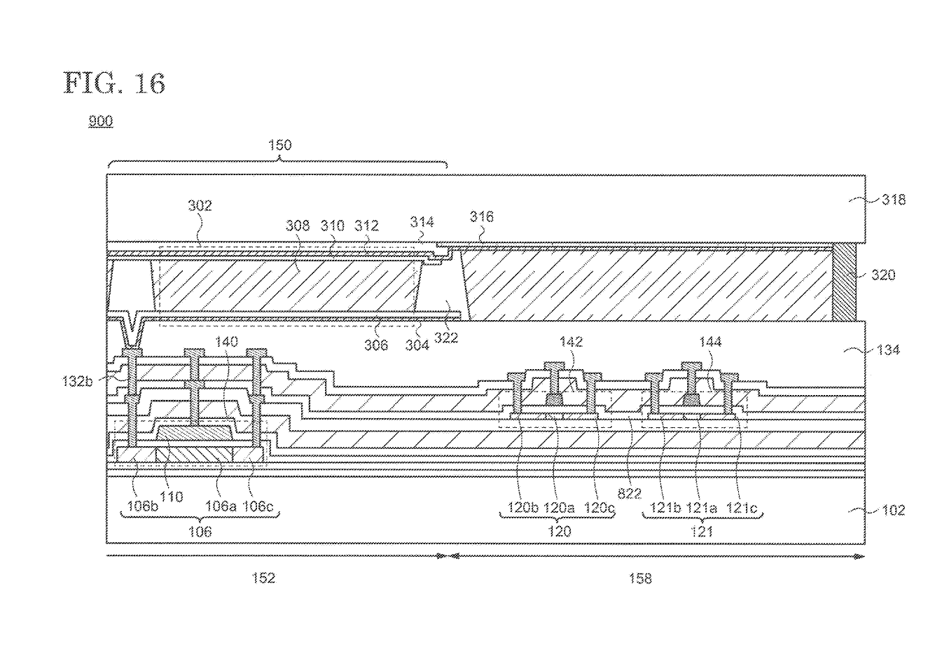

In the present embodiment, a display device including the semiconductor device 100, 200, 300, or 400 described in the First Embodiment and its manufacturing method are explained with reference to FIG. 16. Description which is the same as that in the First to Sixth Embodiments may be omitted.

A schematic cross-sectional view of a display device 900 is shown in FIG. 16. A part of the display region 152 and a part of the driver circuit 158 shown in FIG. 10 are schematically illustrated in FIG. 16. The display device 900 has the semiconductor device 200 described in the First Embodiment, the first transistor 140 including the oxide semiconductor film 106 is provided in the pixel 150 of the display region 152, and the second transistor 142 and the third transistor 144 having the silicon semiconductor films 120 and 121, respectively, are disposed in the driver circuit 158.

Apart from the display device 500, 600, 700, and 800, the display device 900 has a liquid crystal element 302 in the pixel 150. The liquid crystal element 302 has a first electrode 304 over the leveling film 134, a first orientation film 306 over the first electrode 304, a liquid crystal layer 308 over the first orientation film 306, a second orientation film 310 over the liquid crystal layer 308, and a second electrode 312 over the second orientation film 310. A color filter 314 is arranged as an optional structure over the liquid crystal element 302. Additionally, a light-shielding film 316 is formed in a region overlapping with the driver circuit 158.

An opposing substrate 318 is disposed over the liquid crystal element 302 and is fixed to the substrate 102 with a sealing material 320. The liquid crystal layer 308 is sandwiched between the substrate 102 and the opposing substrate 318, and a thickness of the liquid crystal layer 308, that is, a distance between the substrate 102 and the opposing substrate 318 is maintained by a spacer 322. Note that, although not shown, a polarizing plate, a retardation film, or the like may be arranged under the substrate 102 or over the opposing substrate 318.

In the present embodiment, the description is made so that the display device 900 has the so-called VA (Vertical Alignment) type or TN (Twisted Nematic) type liquid crystal element 302. However, the liquid crystal element 302 is not limited to these modes and may have another mode such as the IPS (In-plane-switching) type. When a transmission type liquid crystal element is used, the first transistor 140 may be arranged so as not to overlap with the liquid crystal element 302.

The display device 900 shown in the present embodiment possesses the second transistor 142 and the third transistor 144 including the silicon semiconductor films 120 and 121, respectively, in the driver circuit 158. As a transistor including a silicon semiconductor film, especially, a transistor including a polycrystalline silicon semiconductor film has a high field-effect mobility, the driver circuit 158 including these transistors is capable of high-speed operation. On the other hand, the pixel 150 possesses the first transistor 140 including the oxide semiconductor film 106. As a transistor including an oxide semiconductor has small variation of the threshold voltage, variation of the voltage applied to the liquid crystal element 302 can be reduced. As a result, the variation in transmittance of the liquid crystal element 302 is decreased, and a display device capable of supplying a high quality image can be provided.

The aforementioned modes described as the embodiments of the present invention can be implemented by appropriately combining with each other as long as no contradiction is caused. Furthermore, any mode which is realized by the persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by the persons ordinarily skilled in the art.

What is claimed is:

1. A semiconductor device comprising:
a substrate;
a first transistor over the substrate, the first transistor including an oxide semiconductor film;
an interlayer film over the first transistor; and
a second transistor over the interlayer film, the second transistor comprising a semiconductor film including silicon.

2. The semiconductor device according to claim 1,
wherein:
the first transistor comprises:
the oxide semiconductor film;
a first gate insulating film over the oxide semiconductor film; and
a first gate over the first gate insulating film;
the interlayer film includes an inorganic insulator; and
the second transistor comprises:
the semiconductor film;
a second gate insulating film over the semiconductor film; and
a second gate over the second gate insulating film.

3. The semiconductor device according to claim 1,
wherein the semiconductor film comprises polycrystalline silicon.

4. The semiconductor device according to claim 1,
wherein the interlayer film comprises:
a first layer including silicon oxide;
a second layer over the first layer, the second layer including silicon nitride; and
a third layer over the second layer, the third layer including silicon oxide.

5. The semiconductor device according to claim 1, further comprising:
a metal film under the first transistor, the metal film being located between the substrate and the oxide semiconductor film.

6. The semiconductor device according to claim 2,
wherein the second gate includes aluminum.

7. A display device comprising:
a substrate;
a display region over the substrate, the display region comprising a pixel including a display element; and
a driver circuit over the substrate, the driver circuit being configured to control the display element,
wherein the pixel comprises:
a first transistor including an oxide semiconductor film and electrically connected to the display element;
an interlayer film over the first transistor; and
a second transistor over the interlayer film, the second transistor being electrically connected to the first transistor and including a semiconductor film including silicon.

8. The display device according to claim 7,
wherein:
the first transistor comprises:
the oxide semiconductor film;
a first gate insulating film over the oxide semiconductor film; and
a first gate over the first gate insulating film;
the interlayer film includes an inorganic insulator; and
the second transistor comprises:
the semiconductor film;
a second gate insulating film over the semiconductor film; and
a second gate over the second gate insulating film.

9. The display device according to claim 7,
wherein the driver circuit is located outside the display region and comprises a third transistor including an oxide semiconductor film.

10. The display device according to claim 7,
wherein the interlayer film comprises:
a first layer including silicon oxide;
a second layer over the first layer, the second layer including silicon nitride; and
a third layer over the second layer, the third layer including silicon oxide.

11. The display device according to claim 7,
wherein the pixel comprises a metal film between the oxide semiconductor film and the substrate.

12. The display device according to claim 7,
wherein:
the pixel comprises:
a driving transistor in which one of source-drain electrodes is connected to an electrode of the display element; and
a switching transistor in which one of source-drain electrodes is connected to a gate electrode of the driving transistor;
the first transistor is the driving transistor; and
the second transistor is the switching transistor.

13. The display device according to claim 8,
wherein the second gate includes aluminum.

14. A method for manufacturing a semiconductor device, the method comprising:
forming a first transistor including an oxide semiconductor film over a substrate;
forming an interlayer film over the first transistor; and
forming a second transistor over the interlayer film, the second transistor being electrically connected to the first transistor and comprising a semiconductor film including silicon.

15. The method according to claim 14,
wherein:
the first transistor comprises:
the oxide semiconductor film;
a first gate insulating film over the oxide semiconductor film; and
a first gate over the first gate insulating film;
the interlayer film includes an inorganic insulator; and
the second transistor comprises:
the semiconductor film;
a second gate insulating film over the semiconductor film; and
a second gate over the second gate insulating film.

16. The method according to claim 14,
wherein the semiconductor film comprises polycrystalline silicon.

17. The method according to claim 14,
wherein the interlayer film comprises:
a first layer including silicon oxide;
a second layer over the first layer, the second layer including silicon nitride; and
a third layer over the second layer, the third layer including silicon oxide.

18. The method according to claim 14, further comprising:
forming a metal film under the first transistor.

19. The method according to claim 14, further comprising:
heating the oxide semiconductor film at a temperature from 250° C. to 500° C.

20. The method according to claim 15, including:
simultaneously performing laser irradiation on the oxide semiconductor film and the semiconductor film.
